(19) United States
(12) Patent Application Publication
(10) Pub. No.: US 2006/0134831 A1
(43) Pub. Date: Jun. 22, 2006

(54) Integrated circuit packaging using electrochemically fabricated structures

(75) Inventors: Adam L. Cohen, Van Nuys, CA (US); Vacit Arat, La Canada Flintridge, CA (US); Michael S. Lockard, Lake Elizabeth, CA (US); Christopher R. Folk, Los Angeles, CA (US); Marvin M. Kilgo III, Oakland, CA (US)

Correspondence Address: Microfabrica Inc., 1103 W. Isabel St., Burbank, CA, 91506, US

(73) Assignee: Microfabrica Inc.

(21) Appl. No.: 11/207,477

(22) Filed: Aug. 19, 2005

Related U.S. Application Data
(63) Continuation-in-part of application No. 11/028,945, filed on Jan. 3, 2005.
(60) Provisional application No. 60/533,948, filed on Dec. 31, 2003.
(60) Provisional application No. 60/574,737, filed on May 26, 2004.
(60) Provisional application No. 60/610,083, filed on Sep. 14, 2004.
(60) Provisional application No. 60/603,030, filed on Aug. 19, 2004.

(51) Int. Cl. H01L 21/50; H01L 21/48

(52) U.S. Cl. 438/108; 438/121; 438/106; 438/122

(57) ABSTRACT

Embodiments of the invention provide methods for packaging integrated circuits and/or other electronic components with electrochemically fabricated structures which include conductive interconnection elements. In some embodiments the electrochemically produced structures are fabricated on substrates that include conductive vias while in other embodiments, the substrates are solid blocks of conductive material, or conductive material containing passages that allow the flow of fluid to maintain desired thermal properties of the packaged electronic components.

### RELATED APPLICATIONS

This application claims benefit of U.S. Provisional Patent Application Nos. 60/603,030, filed Aug. 19, 2004, and 60/610,083, filed Sep. 14, 2004, and is a continuation-in-part of U.S. patent application Ser. No. 11/028,945, filed Jan. 3, 2005 which in turn claims benefit of U.S. Provisional Application Nos. 60/533,948, filed Dec. 31, 2003, and 60/574,737, filed May 26, 2004. Each of these applications is incorporated herein by reference as if set forth in full herein.

### FIELD OF THE INVENTION

The present invention relates generally to the field of Electrochemical Fabrication and the associated formation of three-dimensional structures (e.g. microscale or mesoscale structures). In particular, it relates to electrochemical fabrication methods for fabricating packages for Integrated Circuits where at least a portion of the package is formed using electrochemical fabrication techniques.

### BACKGROUND OF THE INVENTION

A technique for forming three-dimensional structures (e.g. parts, components, devices, and the like) from a plurality of adhered layers was invented by Adam L. Cohen and is known as Electrochemical Fabrication. It is being commercially pursued by Microfabrica Inc. (formerly MEMGen® Corporation) of Burbank, Calif. under the name EFAB™. This technique was described in U.S. Pat. No. 6,027,630, issued on Feb. 22, 2000. This electrochemical deposition technique allows the selective deposition of a material using a unique masking technique that involves the use of a mask that includes patterned conformable material on a support structure that is independent of the substrate onto which plating will occur. When desiring to perform an electrodeposition using the mask, the conformable portion of the mask is brought into contact with a substrate while in the presence of a plating solution such that the contact of the conformable portion of the mask to the substrate inhibits deposition at selected locations. For convenience, these masks might be generically called conformable contact masks; the masking technique may be generically called a conformable contact mask plating process. More specifically, in the terminology of Microfabrica Inc. (formerly MEMGen® Corporation) of Burbank, Calif. such masks have come to be known as INSTANT MASKS™ and the process known as INSTANT MASKING™ or INSTANT MASK™ plating. Selective depositions using conformable contact mask plating may be used to form single layers of material or may be used to form multi-layer structures. The teachings of the '630 patent are hereby incorporated herein by reference as if set forth in full herein. Since the filing of the patent application that led to the above noted patent, various papers about conformable contact mask plating (i.e. INSTANT MASKING) and electrochemical fabrication have been published:
(1) A. Cohen, G. Zhang, F. Tseng, F. Mansfeld, U. Frodis and P. Will, “EFAB: Batch production of functional, fully-dense metal parts with micro-scale features”, Proc. 9th Solid Freeform Fabrication, The University of Texas at Austin, p 161, August 1998.
(2) A. Cohen, G. Zhang, F. Tseng, F. Mansfeld, U. Frodis and P. Will, “EFAB: Rapid, Low-Cost Desktop Micromachining of High Aspect Ratio True 3-D MEMS”, Proc. 12th IEEE Micro Electro Mechanical Systems Workshop, IEEE, p 244, January 1999.
(3) A. Cohen, “3-D Micromachining by Electrochemical Fabrication”, Micromachine Devices, March 1999.
(4) G. Zhang, A. Cohen, U. Frodis, F. Tseng, F. Mansfeld, and P. Will, “EFAB: Rapid Desktop Manufacturing of True 3-D Microstructures”, Proc. 2nd International Conference on Integrated MicroNanotechnology for Space Applications, The Aerospace Co., April 1999.
(5) F. Tseng, U. Frodis, G. Zhang, A. Cohen, F. Mansfeld, and P. Will, “EFAB: High Aspect Ratio, Arbitrary 3-D Metal Microstructures using a Low-Cost Automated Batch Process”, 3rd International Workshop on High Aspect Ratio MicroStructure Technology (HARMST'99), June 1999.
(6) A. Cohen, U. Frodis, F. Tseng, G. Zhang, F. Mansfeld, and P. Will, “EFAB: Low-Cost, Automated Electrochemical Batch Fabrication of Arbitrary 3-D Microstructures”, Micromachining and Microfabrication Process Technology, SPIE 1999 Symposium on Micromachining and Microfabrication, September 1999.
(7) F. Tseng, G. Zhang, U. Frodis, A. Cohen, F. Mansfeld, and P. Will, “EFAB: High Aspect Ratio, Arbitrary 3-D Metal Microstructures using a Low-Cost Automated Batch Process”, MEMS Symposium, ASME 1999 International Mechanical Engineering Congress and Exposition, November, 1999.
(8) A. Cohen, “Electrochemical Fabrication (EFAB™)”, Chapter 19 of The MEMS Handbook, edited by Mohamed Gad-EI-Hak, CRC Press, 2002.
(9) Microfabrication—Rapid Prototyping's Killer Application”, pages 1-5 of the Rapid Prototyping Report, CAD/CAM Publishing, Inc., June 1999.

The disclosures of these nine publications are hereby incorporated herein by reference as if set forth in full herein.

The electrochemical deposition process may be carried out in a number of different ways as set forth in the above patent and publications. In one form, this process involves the execution of three separate operations during the formation of each layer of the structure that is to be formed:
1. Selectively depositing at least one material by electrodeposition upon one or more desired regions of a substrate.
2. Then, blanket depositing at least one additional material by electrodeposition so that the additional deposit covers both the regions that were previously selectively deposited onto, and the regions of the substrate that did not receive any previously applied selective depositions.
3. Finally, planarizing the materials deposited during the first and second operations to produce a smoothed surface of a first layer of desired thickness having at least one region containing the at least one material and at least one region containing at least the one additional material.

After formation of the first layer, one or more additional layers may be formed adjacent to the immediately preceding layer and adhered to the smoothed surface of that preceding layer. These additional layers are formed by repeating the first through third operations one or more times wherein the formation of each subsequent layer treats the previously formed layers and the initial substrate as a new and thickening substrate.

Once the formation of all layers has been completed, at least a portion of at least one of the materials deposited is generally removed by an etching process to expose or release the three-dimensional structure that was intended to be formed.

The preferred method of performing the selective electrodeposition involved in the first operation is by conformable contact mask plating. In this type of plating, one or more conformable contact (CC) masks are first formed. The CC masks include a support structure onto which a patterned conformable dielectric material is adhered or formed. The conformable material for each mask is shaped in accordance with a particular cross-section of material to be plated. At least one CC mask is needed for each unique cross-sectional pattern that is to be plated.

The support for a CC mask is typically a plate-like structure formed of a metal that is to be selectively electroplated and from which material to be plated will be dissolved. In this typical approach, the support will act as an anode in an electroplating process. In an alternative approach, the support may instead be a porous or otherwise perforated material through which deposition material will pass during an electroplating operation on its way from a distal anode to a deposition surface. In either approach, it is possible for CC masks to share a common support, i.e. the patterns of conformable dielectric material for plating multiple layers of material may be located in different areas of a single support structure. When a single support structure contains multiple plating patterns, the entire structure is referred to as the CC mask while the individual plating masks may be referred to as “submasks”. In the present application such a distinction will be made only when relevant to a specific point being made.

In preparation for performing the selective deposition of the first operation, the conformable portion of the CC mask is placed in registration with and pressed against a selected portion of the substrate (or onto a previously formed layer or onto a previously deposited portion of a layer) on which deposition is to occur. The pressing together of the CC mask and substrate occur in such a way that all openings, in the conformable portions of the CC mask contain plating solution. The conformable material of the CC mask that contacts the substrate acts as a barrier to electrodeposition while the openings in the CC mask that are filled with electroplating solution act as pathways for transferring material from an anode (e.g. the CC mask support) to the non-contacted portions of the substrate (which act as a cathode during the plating operation) when an appropriate potential and/or current are supplied.

An example of a CC mask and CC mask plating are shown in FIGS. 1A-1C. FIG. 1A shows a side view of a CC mask 8 consisting of a conformable or deformable (e.g. elastomeric) insulator 10 patterned on an anode 12. The anode has two functions. FIG. 1A also depicts a substrate 6 separated from mask 8. One is as a supporting material for the patterned insulator 10 to maintain its integrity and alignment since the pattern may be topologically complex (e.g., involving isolated “islands” of insulator material). The other function is as an anode for the electroplating operation. CC mask plating selectively deposits material 22 onto a substrate 6 by simply pressing the insulator against the substrate then electrodepositing material through apertures 26a and 26b in the insulator as shown in FIG. 1B. After deposition, the CC mask is separated, preferably non-destructively, from the substrate 6 as shown in FIG. 1C. The CC mask plating process is distinct from a “through-mask” plating process in that in a through-mask plating process the separation of the masking material from the substrate would occur destructively. As with through-mask plating, CC mask plating deposits material selectively and simultaneously over the entire layer. The plated region may consist of one or more isolated plating regions where these isolated plating regions may belong to a single structure that is being formed or may belong to multiple structures that are being formed simultaneously. In CC mask plating as individual masks are not intentionally destroyed in the removal process, they may be usable in multiple plating operations.

Another example of a CC mask and CC mask plating is shown in FIGS. 1D-1F. FIG. 1D shows an anode 12′ separated from a mask 8′ that includes a patterned conformable material 10′ and a support structure 20. FIG. 1D also depicts substrate 6 separated from the mask 8′. FIG. 1E illustrates the mask 8′ being brought into contact with the substrate 6. FIG. 1F illustrates the deposit 22′ that results from conducting a current from the anode 12′ to the substrate 6. FIG. 1G illustrates the deposit 22′ on substrate 6 after separation from mask 8′. In this example, an appropriate electrolyte is located between the substrate 6 and the anode 12′ and a current of ions coming from one or both of the solution and the anode are conducted through the opening in the mask to the substrate where material is deposited. This type of mask may be referred to as an anodeless INSTANT MASK™ (AIM) or as an anodeless conformable contact (ACC) mask.

Unlike through-mask plating, CC mask plating allows CC masks to be formed completely separate from the fabrication of the substrate on which plating is to occur (e.g. separate from a three-dimensional (3D) structure that is being formed). CC masks may be formed in a variety of ways, for example, a photolithographic process may be used. All masks can be generated simultaneously, prior to structure fabrication rather than during it. This separation makes possible a simple, low-cost, automated, self-contained, and internally-clean “desktop factory” that can be installed almost anywhere to fabricate 3D structures, leaving any required clean room processes, such as photolithography to be performed by service bureaus or the like.

An example of the electrochemical fabrication process discussed above is illustrated in FIGS. 2A-2F. These figures show that the process involves deposition of a first material 2 which is a sacrificial material and a second material 4 which is a structural material. The CC mask 8, in this example, includes a patterned conformable material (e.g. an elastomeric dielectric material) 10 and a support 12 which is made from deposition material 2. The conformal portion of the CC mask is pressed against substrate 6 with a plating solution 14 located within the openings 16 in the conformable material 10. An electric current, from power supply 18, is then passed through the plating solution 14 via (a) support 12 which doubles as an anode and (b) substrate 6 which doubles as a cathode. FIG. 2A illustrates that the passing of current causes material 2 within the plating solution and material 2 from the anode 12 to be selectively transferred to and plated on the cathode 6. After electroplating the first deposition material 2 onto the substrate 6 using CC mask 8, the CC mask 8 is removed as shown in FIG. 2B. FIG. 2C depicts the second deposition material 4 as having been blanket-deposited (i.e. non-selectively deposited) over the previously deposited first deposition material 2 as well as over the other portions of the substrate 6. The blanket deposition occurs by electroplating from an anode (not shown), composed of the second material, through an appropriate plating solution (not shown), and to the cathode/substrate 6. The entire two-material layer is then planarized to achieve precise thickness and flatness as shown in FIG. 2D. After repetition of this process for all layers, the multi-layer structure 20 formed of the second material 4 (i.e. structural material) is embedded in first material 2 (i.e. sacrificial material) as shown in FIG. 2E. The embedded structure is etched to yield the desired device, i.e. structure 20, as shown in FIG. 2F.

Various components of an exemplary manual electrochemical fabrication system 32 are shown in FIGS. 3A-3C. The system 32 consists of several subsystems 34, 36, 38, and 40. The substrate holding subsystem 34 is depicted in the upper portions of each of FIGS. 3A-3C and includes several components: (1) a carrier 48, (2) a metal substrate 6 onto which the layers are deposited, and (3) a linear slide 42 capable of moving the substrate 6 up and down relative to the carrier 48 in response to drive force from actuator 44. Subsystem 34 also includes an indicator 46 for measuring differences in vertical position of the substrate which may be used in setting or determining layer thicknesses and/or deposition thicknesses. The subsystem 34 further includes feet 68 for carrier 48 which can be precisely mounted on subsystem 36.

The CC mask subsystem 36 shown in the lower portion of FIG. 3A includes several components: (1) a CC mask 8 that is actually made up of a number of CC masks (i.e. submasks) that share a common support/anode 12, (2) precision X-stage 54, (3) precision Y-stage 56, (4) frame 72 on which the feet 68 of subsystem 34 can mount, and (5) a tank 58 for containing the electrolyte 16. Subsystems 34 and 36 also include appropriate electrical connections (not shown) for connecting to an appropriate power source for driving the CC masking process.

The blanket deposition subsystem 38 is shown in the lower portion of FIG. 3B and includes several components: (1) an anode 62, (2) an electrolyte tank 64 for holding plating solution 66, and (3) frame 74 on which the feet 68 of subsystem 34 may sit. Subsystem 38 also includes appropriate electrical connections (not shown) for connecting the anode to an appropriate power supply for driving the blanket deposition process.

The planarization subsystem 40 is shown in the lower portion of FIG. 3C and includes a lapping plate 52 and associated motion and control systems (not shown) for planarizing the depositions.

Another method for forming microstructures from electroplated metals (i.e. using electrochemical fabrication techniques) is taught in U.S. Pat. No. 5,190,637 to Henry Guckel, entitled “Formation of Microstructures by Multiple Level Deep X-ray Lithography with Sacrificial Metal layers”. This patent teaches the formation of metal structures utilizing mask exposures. A first layer of a primary metal is electroplated onto an exposed plating base to fill a void in a photoresist, the photoresist is then removed and a secondary metal is electroplated over the first layer and over the plating base. The exposed surface of the secondary metal is then machined down to a height which exposes the first metal to produce a flat uniform surface extending across the both the primary and secondary metals. Formation of a second layer may then begin by applying a photoresist layer over the first layer and then repeating the process used to produce the first layer. The process is then repeated until the entire structure is formed and the secondary metal is removed by etching. The photoresist is formed over the plating base or previous layer by casting and the voids in the photoresist are formed by exposure of the photoresist through a patterned mask via X-rays or UV radiation.

Even though electrochemical fabrication as taught and practiced to date, has greatly enhanced the capabilities of microfabrication, and in particular added greatly to the number of metal layers that can be incorporated into a structure and to the speed and simplicity in which such structures can be made, room for enhancing the state of electrochemical fabrication exists as well as for adding to the types of devices that can be formed or co-fabricated with other devices. In particular, a need exists in the art for improved methods of packaging semiconductor devices.

### SUMMARY OF THE INVENTION

It is an object of some aspects of the invention to provide improved method for packing integrated circuits or other semiconductor devices.

It is an object of some aspects of the invention to provide improved packages for integrated circuits or improved packaged integrated circuits.

Other objects and advantages of various aspects of the invention will be apparent to those of skill in the art upon review of the teachings herein. The various aspects of the invention, set forth explicitly herein or otherwise ascertained from the teachings herein, may address one or more of the above objects alone or in combination, or alternatively may address some other object of the invention ascertained from the teachings herein. It is not intended that all objects be addressed by any single aspect of the invention even though that may be the case with regard to some aspects.

In a first aspect of the invention a process for fabricating a packaged electronic component includes: providing a substrate having conductive vias; forming routing elements on the substrate which have first and second ends, where at least some of the first ends are connectable to a first electronic component and at least some of the second ends are electrically connected to vias on the substrate; and connecting the first electronic component to the at least some of the first ends.

In a second aspect of the invention a process for fabricating a packaged electronic component includes: providing a substrate having conductive vias; forming routing elements which have first and second ends, where at least some of the first ends are connectable to a first electronic component and at least some of the second ends are connectable to vias on the substrate; electrically connecting the at least some of the second ends to the vias comprising a bonding operation; and electrically connecting the first electronic component to the at least some of the first ends.

In a third aspect of the invention a process for fabricating a plurality of packaged electronic components includes: providing a substrate; forming routing elements on the substrate which have first and second ends, where at least some of the first ends are electrically connectable to a first electronic component and at least some of the second ends are electrically connectable to a second electronic component; and attaching the first and second electronic components to the at least some of the first ends and second ends, respectively.

In a fourth aspect of the invention a process for fabricating a plurality of packaged electronic components includes: providing a substrate; forming routing elements which have first and second ends, where at least some of the first ends are electrically connectable to a first electronic component and at least some of the second ends are electrically connectable to a second electronic component; establishing a thermally conductive connection between the substrate and routing elements; and electrically connecting the first and second electronic components to the at least some of the first ends and second ends, respectively.

In a fifth aspect of the invention a fabrication process for fabricating a package for holding an electronic component includes: (a) forming and adhering a layer of material to a previously formed layer and/or to a substrate, wherein the layer comprises a desired pattern of at least one material; and (b) repeating the forming and adhering operation of (a) a plurality of times to build up a configuration of conductive interconnect elements, wherein the plurality of layers are adhered to one another and comprise at least one of (i) at least one structural material and at least one sacrificial material or (ii) at least two structural materials one of which is a conductor and one of which is a dielectric; and wherein at least one of the following is true: (1) the package comprises metal electrodeposited or electroless deposited on a layer-by-layer basis where the height of at least some layers is set by a planarization operation that planarizes an interconnect material and at least one other material; (2) the package comprises vias and traces that coexist on at least some layers; (3) the package comprises at least one more coaxial interconnects; (4) the package comprises interconnects having traces having at least two different widths; (5) the package comprises interconnects comprising vias that have at least two different widths; (6) the package comprises interconnects having trace thicknesses that are at least as thick as some planarized thicknesses of a dielectric material; (7) the package comprises interconnects having trace thicknesses that are at least as thick as the differential height between some interconnect traces; (8) the at least one layer of the package is formed using a process comprising: patterning a first material, applying a non-planar seed layer, electrodepositing a second material, and trimming off at least a portion of the deposited first material.

Further aspects of the invention will be understood by those of skill in the art upon reviewing the teachings herein. Other aspects of the invention may involve combinations of the above noted aspects of the invention. Other aspects of the invention may involve apparatus that are configured to implement one or more of the above method aspects of the invention. Other aspects of the invention may involve products produced by the above method aspects of the invention or products produced by other methods. These other aspects of the invention may provide various combinations of the aspects, embodiments, and associated alternatives explicitly set forth herein as well as provide other configurations, structures, functional relationships, and processes that have not been specifically set forth above.

### BRIEF DESCRIPTION OF THE DRAWINGS

FIGS. 1A-1C schematically depict side views of various stages of a CC mask plating process, while FIGS. 1D-G schematically depict a side views of various stages of a CC mask plating process using a different type of CC mask.

FIGS. 2A-2F schematically depict side views of various stages of an electrochemical fabrication process as applied to the formation of a particular structure where a sacrificial material is selectively deposited while a structural material is blanket deposited.

FIGS. 3A-3C schematically depict side views of various example subassemblies that may be used in manually implementing the electrochemical fabrication method depicted in FIGS. 2A-2F.

FIGS. 4A-4I schematically depict the formation of a first layer of a structure using adhered mask plating where the blanket deposition of a second material overlays both the openings between deposition locations of a first material and the first material itself.

FIGS. 5A-5D schematically depict side views of various stages in a process for attaching an example IC to an example package where interconnects from the IC to at least one other component include vias that extend through a substrate on which electrochemically fabricated routing elements are formed.

FIG. 6 schematically depicts a side view of two example ICs attached to and at least partially electrically interconnected to one another via an example package and where at least a portion of the interconnects extend through routing elements formed via electrochemical fabrication methods.

FIG. 7 schematically depicts a side view of an example IC attached to an alternative example package configuration, where the package configuration includes a conductive substrate, routing elements that provide interconnect paths from a surface of the package to the IC, and which includes optional passive components such as inductors and capacitors.

FIG. 8 schematically depicts a side view of an example IC attached to a package configuration similar to that of FIG. 7 with the exception that the substrate includes a passage for allowing a cooling fluid to pass through the substrate.

FIG. 9 schematically depicts a side view of two example ICs and a package with routing elements and which further includes an added packaging element that takes the form of a heat sink that is located above one of the ICs and which includes a passage through which a cooling liquid may flow.

FIG. 10 schematically depicts a side view of routing elements formed via electrochemical fabrication where a substrate on which the layers were formed has been removed and an IC attached.

### DETAILED DESCRIPTION OF PREFERRED EMBODIMENTS OF THE INVENTION

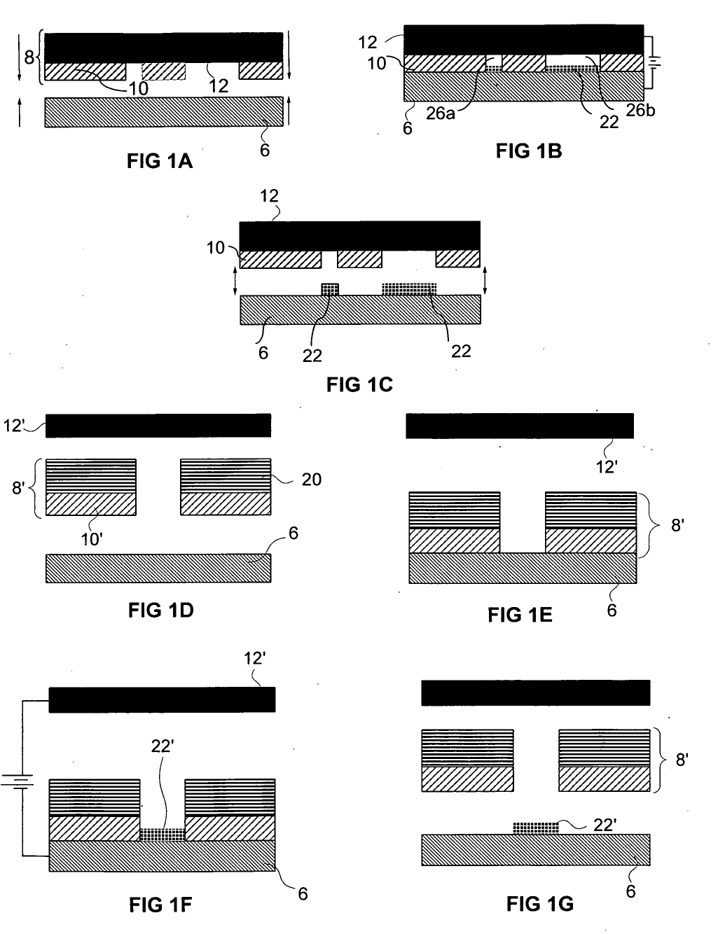

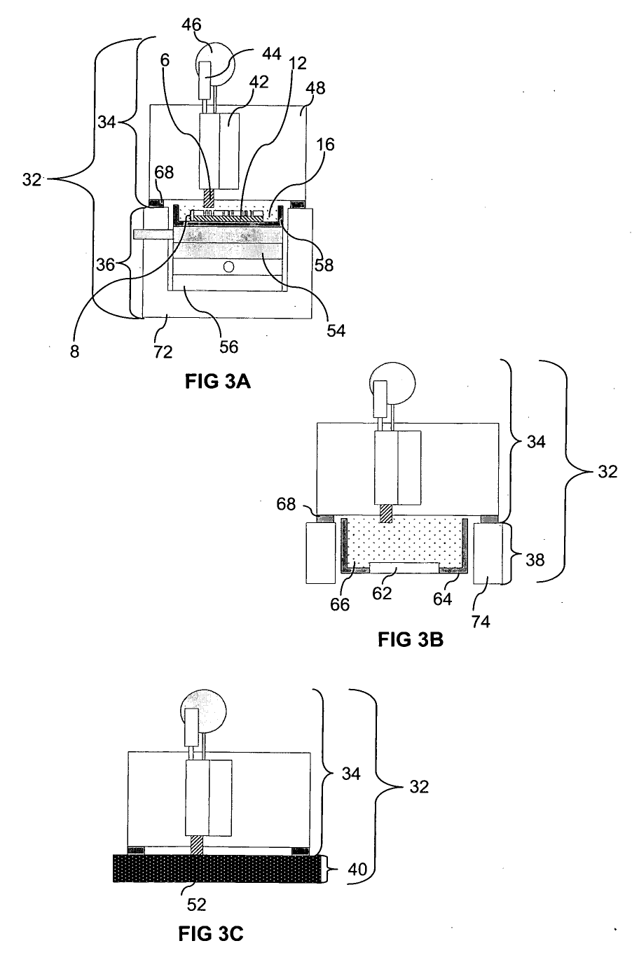

FIGS. 1A-1G, 2A-2F, and 3A-3C illustrate various features of one form of electrochemical fabrication that are known. Other electrochemical fabrication techniques are set forth in the '630 patent referenced above, in the various previously incorporated publications, in various other patents and patent applications incorporated herein by reference, still others may be derived from combinations of various approaches described in these publications, patents, and applications, or are otherwise known or ascertainable by those of skill in the art from the teachings set forth herein. All of these techniques may be combined with those of the various embodiments of various aspects of the invention to yield enhanced embodiments. Still other embodiments may be derived from combinations of the various embodiments explicitly set forth herein.

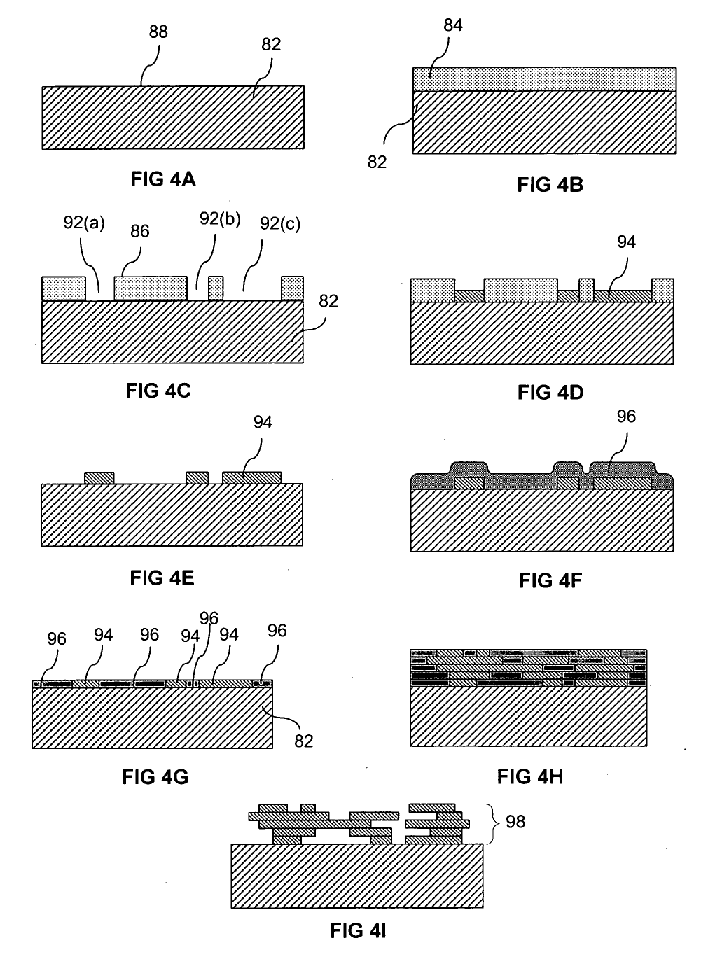

FIGS. 4A-4I illustrate various stages in the formation of a single layer of a multi-layer fabrication process where a second metal is deposited on a first metal as well as in openings in the first metal where its deposition forms part of the layer. In FIG. 4A, a side view of a substrate 82 is shown, onto which patternable photoresist 84 is cast as shown in FIG. 4B. In FIG. 4C, a pattern of resist is shown that results from the curing, exposing, and developing of the resist. The patterning of the photoresist 84 results in openings or apertures 92(a)-92(c) extending from a surface 86 of the photoresist through the thickness of the photoresist to surface 88 of the substrate 82. In FIG. 4D, a metal 94 (e.g. nickel) is shown as having been electroplated into the openings 92(a)-92(c). In FIG. 4E, the photoresist has been removed (i.e. chemically stripped) from the substrate to expose regions of the substrate 82 which are not covered with the first metal 94. In FIG. 4F, a second metal 96 (e.g., silver) is shown as having been blanket electroplated over the entire exposed portions of the substrate 82 (which is conductive) and over the first metal 94 (which is also conductive). FIG. 4G depicts the completed first layer of the structure which has resulted from the planarization of the first and second metals down to a height that exposes the first metal and sets a thickness for the first layer. In FIG. 4H the result of repeating the process steps shown in FIGS. 4B-4G several times to form a multi-layer structure are shown where each layer consists of two materials. For most applications, one of these materials is removed as shown in FIG. 4I to yield a desired 3-D structure 98 (e.g. component or device).

Various embodiments of various aspects of the invention are directed to formation of three-dimensional structures from materials some of which may be electrodeposited or electroless deposited. Some of these structures may be formed form a plurality of layers of deposited materials (e.g. two or more layers, more preferably five or more layers, and most preferably ten or more layers). In some embodiments structures having features positioned with micron level precision and minimum features size on the order of tens of microns are to be formed. In other embodiments structures with less precise feature placement and/or larger minimum features may be formed. In still other embodiments, higher precision and smaller minimum feature sizes may be desirable.

The various embodiments, alternatives, and techniques disclosed herein may form multi-layer structures using a single patterning technique on all layers or using different patterning techniques on different layers. For example, different types of patterning masks and masking techniques may be used or even techniques that perform direct selective depositions without the need for masking. For example, Various embodiments of the invention may perform selective patterning operations using conformable contact masks and masking operations, proximity masks and masking operations (i.e. operations that use masks that at least partially selectively shield a substrate by their proximity to the substrate even if contact is not made), non-conformable masks and masking operations (i.e. masks and operations based on masks whose contact surfaces are not significantly conformable), and/or adhered masks and masking operations (masks and operations that use masks that are adhered to a substrate onto which selective deposition or etching is to occur as opposed to only being contacted to it). Adhered mask may be formed in a number of ways including (1) by application of a photoresist, selective exposure of the photoresist, and then development of the photoresist, (2) selective transfer of pre-patterned masking material, and/or (3) direct formation of masks from computer controlled depositions of material.

Patterning operations may be used in selectively depositing material and/or may be used in the selective etching of material. Selectively etched regions may be selectively filled in or filled in via blanket deposition, or the like, with a different desired material. In some embodiments, the layer-by-layer build up may involve the simultaneous formation of portions of multiple layers. In some embodiments, depositions made in association with some layer levels may result in depositions to regions associated with other layer levels. Such use of selective etching and interlaced material deposited in association with multiple layers is described in U.S. patent application Ser. No. 10/434,519, by Smalley, and entitled “Methods of and Apparatus for Electrochemically Fabricating Structures Via Interlaced Layers or Via Selective Etching and Filling of Voids” which is hereby incorporated herein by reference as if set forth in full.

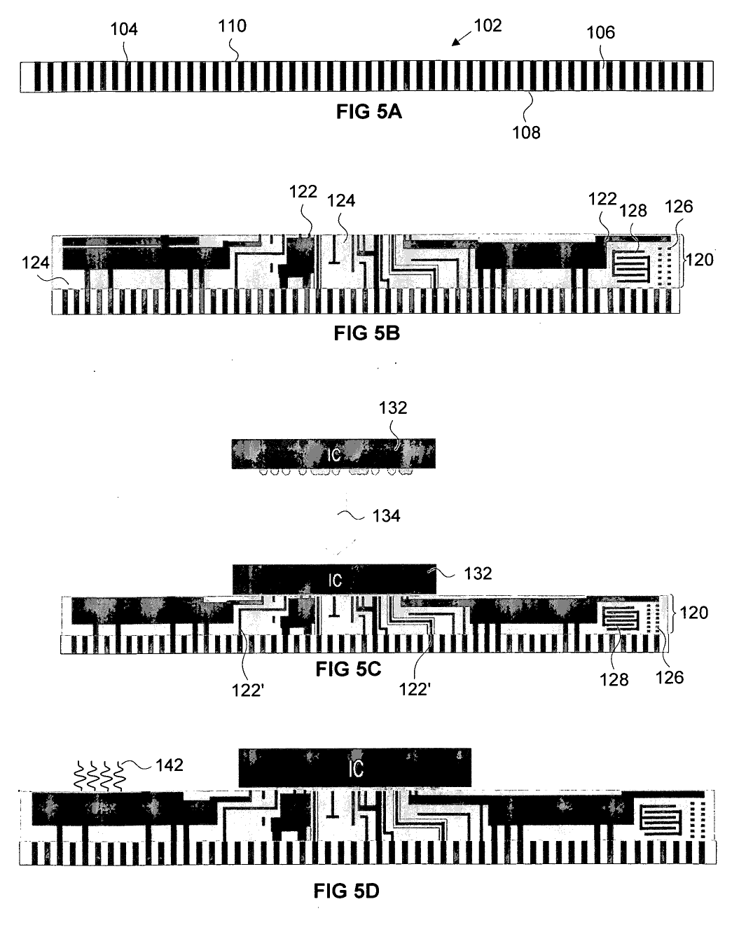

FIGS. 5A-5D schematically depict side views of various stages in a process for attaching an example IC to an example package where interconnects from the IC to at least one other component include vias that extend through a substrate on which electrochemically fabricated routing elements are formed.

FIG. 5A depicts a substrate 102 for use with some embodiments of the invention. The substrate includes a plurality of conductive vias 104 through a dielectric material 106 (e.g. a ceramic, glass, polymer) that extend from a lower surface 108 to an upper surface 110 of the substrate. In some embodiments the vias may be uniformly spaced with a desired pattern while in other embodiments they may be spaced in an irregular pattern. In some embodiments the vias may extend along straight paths perpendicular to the top and bottom surfaces while in other embodiments, the paths may form more complex patterns including merging and/or diverging configurations and/or they may not extend perpendicular to the surfaces. In some embodiments, one or both the top and bottom surfaces may not be planar and/or the surfaces may not be parallel to one another. The substrate 102 may be formed in a variety of ways such as by low temperature co-fired ceramic (LTCC) formation methods, multi-layer ceramic (MLC) formation methods, electrochemical fabrication methods, drilling vias in a dielectric material and filling the vias with conductive material, and the like.

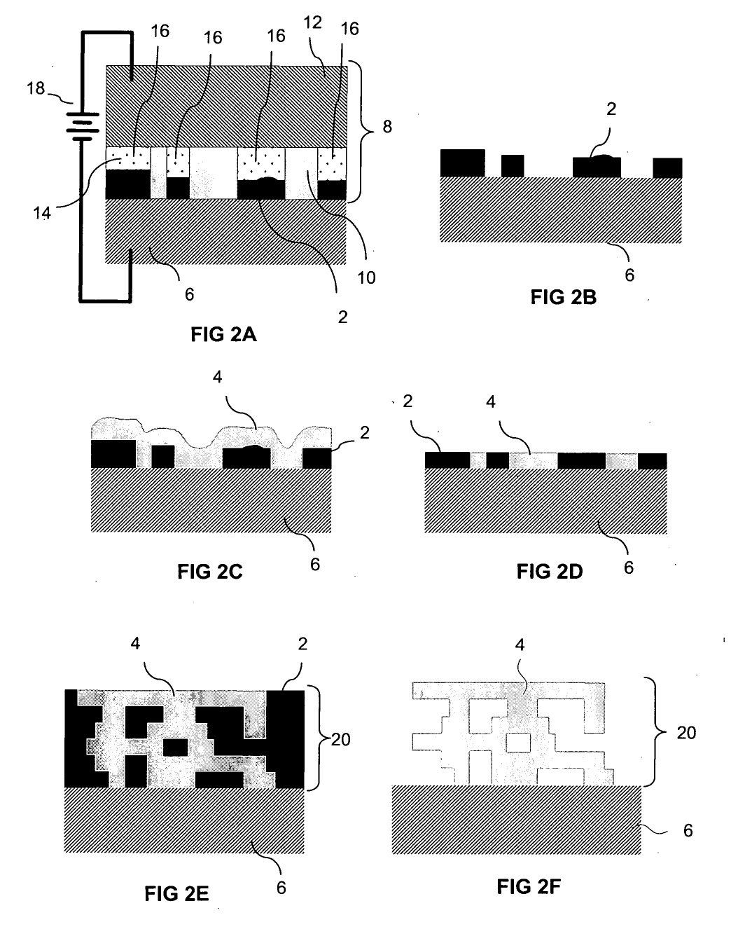

FIG. 5B depicts the state of the process after a plurality of layers 120 have been formed with each having a desired configuration so as to form routing elements 122 via an electrochemical fabrication process. In some embodiments (as shown), the routing elements 122 may be partially encapsulated by a dielectric material 124 while in other embodiments the routing elements may be separated by air or even vacuum or other gas after packaging. The electrochemical fabrication process, for example, may be one of those shown and described in association with FIGS. 2A-2F or 4A-4F or as described in the various other patent applications incorporated herein by reference. In particular, in some embodiments, the electrochemical fabrication process may involve the deposition of a conductive material and a dielectric material during the formation of each layer (e.g. as described in U.S. Patent Application No. 60/574,733, which was filed on May 26, 2004, by Lockard et al., and entitled “Methods for Electrochemically Fabricating Structures Using Adhered Masks, Incorporating Dielectric Sheets, and/or Seed layers That Are Partially Removed Via Planarization”, which is incorporated herein by reference as if set forth in full). In other embodiments, each layer may be formed with a structural material (e.g. a material used in forming routing elements) and a sacrificial material (e.g. a material occupying regions that are to contain a dielectric) where after partial or complete formation of the substrate thickness, the sacrificial material may be transformed into a desired dielectric material or removed and replaced with a desired dielectric material, after which an optional planarization operation may be used to set or reset the thickness of the structure. As shown in FIG. 5B the electrochemically fabricated structure may include various electronic components such as inductor 126 and capacitor 128. In other embodiments, other passive or active devices may be included in the structure while in still other embodiments such electronic devices need not be formed as part of, or otherwise included in, the structure. In some embodiments, added components may not be embedded in dielectric material but may instead be located within voids in the dielectric material.

In some embodiments, the formation of layers 120 may occur one after another with the first being adhered to the substrate 102. In other embodiments, the layers 120 may be formed on a sacrificial substrate or on a temporary substrate on which a release layer exists and after formation (and potentially testing) the structure defined by layers 120 may be transferred and bonded to substrate 102 and released from the sacrificial or temporary substrate and release layer. Examples of the transfer and release of structures may be found in U.S. patent application Ser. No. 11/173,241, filed Jun. 30, 2005, by Kumar, et al., and entitled Probe Arrays and Method for Making; and U.S. patent application Ser. No. 10/841,006, filed May 7, 2004, by Thompson, et al., and entitled Electrochemically Fabricated Structures Having Dielectric or Active Bases and Methods of and Apparatus for Producing Such Structures, and published as 2005/0067292. Each of these applications is incorporated herein by reference.

FIG. 5C shows the state of the process after an IC 132 is moved along arrow 134 and brought into contact with the electrochemically fabricated layers 120, after which they may be bonded or otherwise connected to one another (e.g. via flip-chip attachment). Such bonding may occur, for example, using solder bumps 136 which are located on the bottom of IC 132. In other embodiments, solder bumps may be additionally or alternatively located on selected portions of the structure 120. In still other embodiments it may be possible to use other bonding or mounting techniques, such as for example, spring contactors, in combination with retention elements such as sockets, clips, hooks, adhesive, or the like. Further teachings concerning retention elements and other retention and alignment structures is provided in U.S. patent application Ser. No. 10/677,556, filed Oct. 1, 2003, by Cohen, et al., and entitled Monolithic Structures Including Alignment and/or Retention Fixtures for Accepting Components, and published as 2004/0134772. The bonding techniques may be different from or similar to those set forth in the previously referenced Ser Nos. 11/173,241 and 10/841,006 applications. Spring contactor may be different or similar to those set forth in U.S. patent application Ser. No. 11/028,960, filed Jan. 3, 2005, by Chen, et al., and entitled Cantilever Microprobes For Contacting Electronic Components and Methods for Making Such Probes; or U.S. patent application Ser. No. 11/029,180, filed Jan. 3, 2005, by Chen, et al., and entitled Pin-Type Probes for Contacting Electronic Circuits and Methods for Making Such Probes; or U.S. patent application Ser. No. 10/949,738, filed Sep. 24, 2004, by Kruglick, et al., and entitled Electrochemically Fabricated Microprobes. These referenced applications are incorporated herein by reference as if set forth in full.

FIG. 5D shows the state of the process after additional components, such as spring elements 142, have been added to the assembly. As can be seen in FIGS. 5C and 5D, various pads on the IC make electric contact with elements 122 (or to pads connected to elements 122) some of which electrically connect various pads of the IC to one another while others connect electric pads of the IC to the vias which in turn may electrically connect to other circuit elements (not shown). As can be seen in FIGS. 5B-5D, some routing elements may be in the form of simple conductive leads 122′ while others may be in the form of shielded 122″ conductive leads (e.g. coaxial elements), while still others may be in the form of waveguides, microstrip, or stripline (not shown), or the like. The routing elements may change dimensions, orientation, and the like for making desired electrical connections, avoiding inappropriate contact with other routing elements, enhancing electrical conductivity, electrical current carrying capacity, thermal conductivity, and/or other attributes of the package. For example, ground (GND) and voltage (VDD) connections may be made with arbitrarily wide for better current supply and lower inductance. Conductive traces in structure 120 may touch selected spots or areas on an IC or on other components to spread heat and/or conduct heat away. These selected spots or areas may be those areas which would otherwise form hot spots or cold spots.

In various embodiments, the substrate 102 of FIGS. 5A-5D may be bonded to or made to electrically contact electrical leads on or extending from other components. In different embodiments, such attachment may be made prior to forming layers 120 on the substrate 102 or after transferring IC 132 to the substrate 102 or at some point between these states.

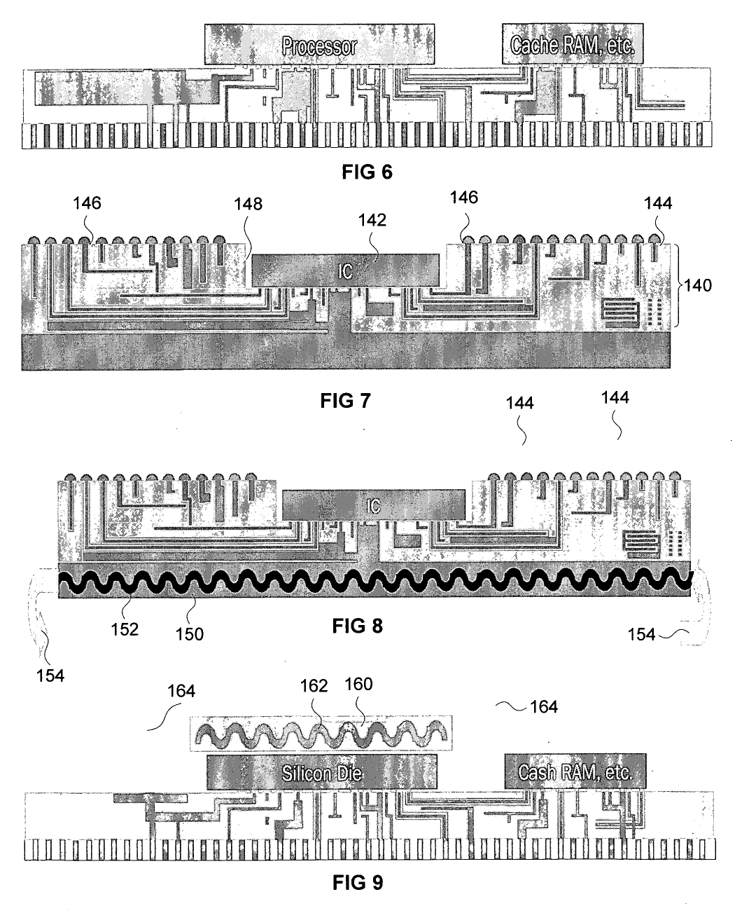

FIG. 6 schematically depicts a side view of two example ICs attached to and at least partially electrically interconnected to one another via an example package where at least a portion of the interconnects extend through routing elements formed via electrochemical fabrication. As shown, some routing elements conduct signals from each IC to the vias in the substrate, and/or from one IC to the other IC. The conducted signals may be shielded (e.g. via coaxial routing elements) or non-shielded, they may be power or ground signals, data signals, clock signals, or the like. As indicated a shielded, e.g. coaxial connection, ultra-high bandwidth connection) may be used between a processor IC (the left IC) and its memory IC (the right IC). Such shielded interconnect elements may provide: (1) non-dispersive signal transmission, (2) little or no cross-talk, (3) low loss (<0.5 dB/cm), (4) vastly improved routing flexibility for shortest point-to-point connections, (5) arbitrary thickness and low-inductance GND & VDD connections, (6) routing of the main clock tree connections off the die for die size savings and power savings, and/or (7) desired impedance matching or signal filtering functions.

FIG. 7 schematically depicts a side view of an example IC attached to an alternative example package configuration, where the package configuration includes a conductive substrate, routing elements that provide interconnect paths from a surface of the package (i.e. an upper surface of the package in this example) to the IC, and which includes passive components such as inductors and capacitors. The routing elements of the electrochemically fabricated structure 140 do not feed signals from the IC 142 to vias that extend through the substrate but instead to pads 146 located on upper surface 144 of structure 140. The pads 146 are covered with solder bumps (in this example) which may be used in establishing electrical and possibly mechanical bonding to another circuit element (not shown). In other embodiments, electrical connections may be established via other elements (e.g. wire bonding, gold/gold bonding, or compliant spring contacts) and/or mechanical attachment may be established via other elements (e.g. adhesives, clips, sockets, or the like). The substrate in the example of FIG. 7 is made of a solid block of conductive material (e.g. copper) which may be useful in helping conduct heat away from IC 142. In some alternative embodiments some insulated vias may pass through the substrate. In other alternative embodiments, the substrate may include ridges or ridges may be cut into the substrate to enhance thermal convection and/or radiative properties. In the embodiment of FIG. 7, the IC 142 is located within an indentation in the electrochemically fabricated structure so that appropriate positioning of the upper surface 144 relative to the IC 142 is obtained. In other embodiments, the IC may have an upper surface (after attachment) that is not below surface 144 but is coincident with it or which is above it.

The opening in the structure 140 into which IC 142 is placed may be formed in a variety of ways, for example, via an electrochemical fabrication process by forming routing elements from a conductive structural material, the opening 148 from a sacrificial material that is eventually removed, and the other regions from a desired dielectric material. Methods allowing such three material formation processes are set forth in a plurality of the patent applications incorporated herein by reference, for example in U.S. patent application Ser. No. 10/434,519. In other embodiments, more than one opening may exist. Each opening may be configured to receive one or a plurality of ICs or other components.

In some alternatives to the embodiments of FIGS. 5A-5D, 6, and 7, the electrochemically fabricated structure may be substantially formed from conductive material which is located in different regions by relative thin or narrow locations of dielectric material such that the dielectric material provides appropriate isolation and impedance characteristics but such that the structure as a whole has improved thermal conductive properties for removal or redistribution of heat from an IC or other electronic component that is mounted on it. In still other embodiments the substrate on which the layers of electrochemically fabricated structures are formed or transferred to may be a dielectric or a composite structure including conductive and dielectric regions.

In other alternatives to the embodiments of FIGS. 5A-5D, 6, and 7, additional passive and/or active components may be included, different types of passive and/or active components may be included in the formed structures. In still other embodiments, passive components may be excluded from the formed structures.

FIG. 8 schematically depicts a side view of an example IC attached to a package whose configuration is similar to that of FIG. 7 with the exception that the substrate 150 includes a passage 152 for allowing a cooling fluid to pass through the substrate as indicated by arrows 154. The cooling fluid may be in the form of a liquid or a gas. In some embodiments, connection lines and a pump may be provided to supply fluid to and remove fluid and heat from the substrate. In some embodiments the connection lines, with or without added fins or the like, may offer sufficient cooling of the fluid while in other embodiments a radiator or radiative structures may be specifically added to a selected location or locations along the feed lines to aid in the removal of heat. In some embodiments a fan may be used to direct or draw air over the radiative elements to help remove heat.

In some embodiments the substrate or a portion of a substrate may be made using electrochemically fabricated layers. Fluid passages may form channels in a heat pipe. These channels may provide paths for enhanced conductivity of heat away from selected areas or paths (e.g. wicking paths) for drawing cooled fluid back to a location from which heat is to be removed. In some embodiments, the paths may be uniformly distributed while in other cases they may be designed to provide tailored heat extraction from selected locations. In some embodiments heat pipe elements may exist within the substrate and/or they may be formed within the electrochemically fabricated layers. After formation of the layers, a desired fluid may be added to the passages and the structure sealed. In some embodiments, substrates may be formed from two or more separately formed structures which are bonded together after formation so as to allow formation of selected passages and/or trenches in the various pieces. Separate formation and/or open formation then folder over and bonding may allow for easier removal of sacrificial material. Filling and sealing of fluid into the passages of a heat pipe may occur in a variety of ways. Sealing may be performed by pinching off a fill tube that is formed as part of the structure. Sealing may be performed blocking an opening with a solder ball Filling may occur after removal of a sacrificial material and before or after bringing separately formed pieces together. Teachings concerning open formation are provided in U.S. Provisional patent application Ser. No. ______ (corresponding to Microfabrica Docket No. P-US148-A-MF), filed Aug. 19, 2005, by Cohen et al., and entitled “Enhanced Electrochemical Fabrication Methods Including Assembly of Split Structures”. This referenced application is incorporated herein by reference as if set forth in full herein.

FIG. 9 schematically depicts a side view of two example ICs and a package with routing elements and which further includes an added packaging element that takes the form of a heat sink 160 that is located above one of the ICs and which includes a passage 162 through which a cooling fluid (e.g. a liquid or gas) may flow as indicated by arrows 164.

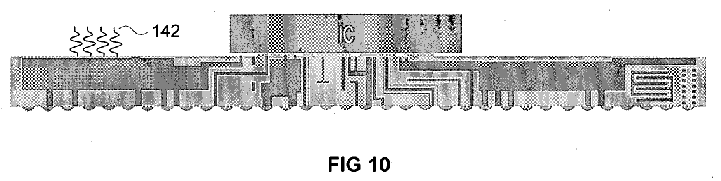

In some alternative embodiments substrates shown in FIGS. 5A-5D, FIG. 6, FIG. 7, and FIG. 9 may be removed after formation of the patterned layers, as shown in FIG. 10. As shown in FIG. 10 solder bumps may be placed on the bottom surface of the routing structure that may be used in making electrical contacts to other elements.

The packaging embodiments provided explicitly herein may be combined with the packaging embodiments provided in U.S. patent application Ser. No. 10/434,103 or 60/681,788, filed on May 7, 2003 and May 16, 2005 respectively, both by Cohen, et al., and both entitled “Electrochemically Fabricated Hermetically Sealed Microstructures and Methods of and Apparatus for Producing Such Structures” to provide hermetically sealed packages. Such packages can protect ICs and other circuit elements from environmental damage while still allowing required electrical, optical, or other inputs and outputs. These referenced applications are incorporated herein by reference as if set forth in full herein.

In some embodiments, the packaging may include separately or integrally formed mechanically active devices (e.g. accelerometers, photonics alignment structures, pressure sensors, other sensors, and the like). Some such devices are disclosed in the various patent applications incorporated herein by reference.

The techniques disclosed herein may benefit by combining them with the techniques disclosed in U.S. patent application Ser. No. 10/841,272 filed May 7, 2004 by Adam Cohen et al. and entitled “Methods and Apparatus for Forming Multi-Layer Structures Using Adhered Masks”. This referenced application is incorporated herein by reference as if set forth in full herein. This referenced application teaches various electrochemical fabrication methods and apparatus for producing multi-layer structures from a plurality of layers of deposited materials where adhered masks are used in selective patterning operations.

The techniques disclosed explicitly herein may benefit by combining them with the techniques disclosed in U.S. patent application Ser. No. 10/697,597 filed on Oct. 29, 2003 by Michael S. Lockard et al. and entitled “EFAB Methods and Apparatus Including Spray Metal or Powder Coating Processes”. This referenced application is incorporated herein by reference as if set forth in full herein. This referenced application teaches various techniques for forming structures via a combined electrochemical fabrication process and a thermal spraying process or powder deposition processes. In some embodiments, selective deposition occurs via masking processes (e.g. a contact masking process or adhered mask process) and thermal spraying or powder deposition is used in blanket deposition processes to fill in voids left by the selective deposition processes. In other embodiments, after selective deposition of a first material, a second material is blanket deposited to fill in the voids, the two depositions are planarized to a common level and then a portion of the first or second materials is removed (e.g. by etching) and a third material is sprayed into the voids left by the etching operation. In both types of embodiments the resulting depositions are planarized to a desired layer thickness in preparation for adding additional layers.

As noted above the formation of the integrated circuit packages may involve a use of structural or sacrificial dielectric materials which may be incorporated into embodiments of the present invention in a variety of different ways. Additional teachings concerning the formation of structures on dielectric substrates and/or the formation of structures that incorporate dielectric materials into the formation process and possibility into the final structures as formed are set forth in a number of provisional and non-provisional patent applications. These filings include U.S. Patent Application Nos. 60/534,184, 11/029,216, and 11/028,957, filed Dec. 31, 2003, Jan. 3, 2005, and Jan. 3, 2005 respectively, which are entitled “Electrochemical Fabrication Methods Incorporating Dielectric Materials and/or Using Dielectric Substrates”; U.S. Patent Application Nos. 60/533,932, filed Dec. 31, 2003, which is entitled “Electrochemical Fabrication Methods Using Dielectric Substrates”; U.S. Patent Application No. 60/534,157, filed Dec. 31, 2003, which is entitled “Electrochemical Fabrication Methods Incorporating Dielectric Materials”; U.S. Patent Application Nos. 60/533,891 and 11/139,262, filed Dec. 31, 2003 and May 26, 2005 respectively, which are entitled “Methods for Electrochemically Fabricating Structures Incorporating Dielectric Sheets and/or Seed layers That Are Partially Removed Via Planarization”; U.S. Patent Application Nos. 60/533,895 and 10/841,378, filed Dec. 31, 2003 and May 7, 2004 respectively which are entitled “Electrochemical Fabrication Method for Producing Multi-layer Three-Dimensional Structures on a Porous Dielectric”. Each of these patent filings are hereby incorporated herein by reference as if set forth in full herein.

Many other alternative embodiments will be apparent to those of skill in the art upon reviewing the teachings herein. Further embodiments may be formed from a combination of the various teachings explicitly set forth in the body of this application. Even further embodiments may be formed by combining the teachings set forth herein above with teachings set forth the patent applications set forth herein after, each of which is incorporated herein by reference:

| US Pat App No, Filing Date | |
|---|---|
| US App Pub No, Pub Date | Inventor, Title |
| 09/493,496 - Jan. 28, 2000 | Cohen, “Method For Electrochemical Fabrication” |
| 10/677,556 - Oct. 1, 2003 | Cohen, “Monolithic Structures Including Alignment and/or |
| | Retention Fixtures for Accepting Components” |
| 10/830,262 - Apr. 21, 2004 | Cohen, “Methods of Reducing Interlayer Discontinuities in |
| | Electrochemically Fabricated Three-Dimensional Structures” |
| 10/271,574 - Oct. 15, 2002 | Cohen, “Methods of and Apparatus for Making High Aspect |
| 2003-0127336A - Jul. 10, | Ratio Microelectromechanical Structures” |
| 2003 | |
| 10/313,795 - Dec. 6, 2005 | Bang, “Complex Microdevices and Apparatus and Methods |
| 2003/0183008 - Oct. 2, 2003 | for Fabricating Such Devices” |
| 10/677,498 - Oct. 1, 2003 | Cohen, “Multi-cell Masks and Methods and Apparatus for |
| | Using Such Masks To Form Three-Dimensional Structures” |
| 10/724,513 - Nov. 26, 2003 | Cohen, “Non-Conformable Masks and Methods and |
| | Apparatus for Forming Three-Dimensional Structures” |
| 10/607,931 - Jun. 27, 2003 | Brown, “Miniature RF and Microwave Components and |
| | Methods for Fabricating Such Components” |
| 10/841,100 - May 7, 2004 | Cohen, “Electrochemical Fabrication Methods Including Use |
| | of Surface Treatments to Reduce Overplating and/or |
| | Planarization During Formation of Multi-layer Three- |
| | Dimensional Structures” |
| 10/387,958 - Mar. 13, 2003 | Cohen, “Electrochemical Fabrication Method and Application |
| 2003-022168A - Dec. 4, 2003 | for Producing Three-Dimensional Structures Having |
| | Improved Surface Finish” |
| 10/434,494 - May 7, 2003 | Zhang, “Methods and Apparatus for Monitoring Deposition |
| 2004-0000489A - Jan. 1, | Quality During Conformable Contact Mask Plating |
| 2004 | Operations” |
| 10/434,289 - May 7, 2003 | Zhang, “Conformable Contact Masking Methods and |
| 20040065555A - Apr. 8, 2004 | Apparatus Utilizing In Situ Cathodic Activation of a |
| | Substrate” |
| 10/434,294 - May 7, 2003 | Zhang, “Electrochemical Fabrication Methods With |
| 2004-0065550A - Apr. 8, | Enhanced Post Deposition Processing Enhanced Post |
| 2004 | Deposition Processing” |
| 10/434,295 - May 7, 2003 | Cohen, “Method of and Apparatus for Forming Three- |
| 2004-0004001A - Jan. 8, | Dimensional Structures Integral With Semiconductor Based |
| 2004 | Circuitry” |
| 10/434,315 - May 7, 2003 | Bang, “Methods of and Apparatus for Molding Structures |
| 2003-0234179 A - Dec. 25, | Using Sacrificial Metal Patterns” |
| 2003 | |
| 10/434,103 - May 7, 2004 | Cohen, “Electrochemically Fabricated Hermetically Sealed |
| 2004-0020782A - Feb. 5, | Microstructures and Methods of and Apparatus for |
| 2004 | Producing Such Structures” |
| 10/841,006 - May 7, 2004 | Thompson, “Electrochemically Fabricated Structures Having |
| | Dielectric or Active Bases and Methods of and Apparatus for |
| | Producing Such Structures” |
| 10/724,515 - Nov. 26, 2003 | Cohen, “Method for Electrochemically Forming Structures |
| | Including Non-Parallel Mating of Contact Masks and |
| | Substrates” |
| 10/841,347 - May 7, 2004 | Cohen, “Multi-step Release Method for Electrochemically |
| | Fabricated Structures” |
| 60/533,947 - Dec. 31, 2003 | Kumar, “Probe Arrays and Method for Making” |
| 60/534,183 - Dec. 31, 2003 | Cohen, “Method and Apparatus for Maintaining Parallelism |
| | of Layers and/or Achieving Desired Thicknesses of Layers |
| | During the Electrochemical Fabrication of Structures” |

Various other embodiments of the present invention exist. Some of these embodiments may be based on a combination of the teachings herein with various teachings incorporated herein by reference. Some embodiments may not use any blanket deposition process and/or they may not use a planarization process. Some embodiments may involve the selective deposition of a plurality of different materials on a single layer or on different layers. Some embodiments may use selective deposition processes or blanket deposition processes on some or all layers that are not electrodeposition processes (e.g. electroless deposition processes. Some embodiments, for example, may use nickel, nickel titanium, nickel cobalt, titanium, stainless steel, gold, copper, tin, silver, zinc, solder, various alloys of these and other and/or dielectric materials as structural materials while other embodiments may use different materials. Some embodiments, for example, may use copper, tin, zinc, solder or other materials and/or dielectric materials as sacrificial materials. Some embodiments may remove a sacrificial material while other embodiments may not. Some embodiments may use photoresist, polyimide, glass, ceramics, other polymers, and the like as dielectric structural materials.

In view of the teachings herein, many further embodiments, alternatives in design and uses of the instant invention will be apparent to those of skill in the art. As such, it is not intended that the invention be limited to the particular illustrative embodiments, alternatives, and uses described above but instead that it be solely limited by the claims presented hereafter.

We claim:

1. A process for fabricating a packaged electronic component, comprising:
providing a substrate having conductive vias;
forming routing elements on the substrate which have first and second ends, where at least some of the first ends are connectable to a first electronic component and at least some of the second ends are electrically connected to vias on the substrate; and
connecting the first electronic component to the at least some of the first ends.

2. The process of claim 1 wherein the forming of the routing elements comprises formation of a plurality of layers of successively deposited materials, wherein a first material comprises a structural conductive material and a second material comprises a dielectric material.

3. The process of claim 2 wherein at least one of the materials is deposited in a selective manner.

4. The process of claim 3 wherein the formation of each of at least a plurality of layers involves a planarization operation.

5. The process of claim 4 wherein at the conductive structural material is deposited via an electrodeposition operation.

6. The process of claim 4 wherein at the conductive structural material is deposited via an electroless deposition operation.

7. The process of claim 1 wherein the connecting comprises a bonding process.

8. The process of claim 1 wherein the connecting comprises a solder bonding process.

9. The process of claim 1 wherein the connecting comprises spring contacts.

10. The process of claim 1 wherein the forming of the routing elements comprises formation of a plurality of layers of successively deposited materials, wherein a first material comprises a structural conductive material and a second material comprises a conductive sacrificial material.

11. The process of claim 10 wherein at least one of the materials is deposited in a selective manner.

12. The process of claim 11 wherein the formation of each of at least a plurality of layers involves a planarization operation.

13. The process of claim 12 wherein at least one of the conductive materials is deposited via an electrodeposition operation.

14. The process of claim 12 wherein at least one of the conductive structural materials is deposited via an electroless deposition operation.

15. The process of claim 2 wherein the formation of the plurality of layers additional comprise formation of a structure that may function as a heat pipe.

16. The process of claim 15 wherein the structure that may function as a heat pipe includes an opening and a hollow stem, after removal of any sacrificial material, wherein the stem may be sealed by crimping after insertion of a desired fluid into the opening.

17. The process of claim 15 wherein the structure that may function as a heat pipe includes a cavity having different sized openings in different areas which provide different sized fluid flow paths which may carry different amounts of heat away from or to the different areas.

18. The process of claim 2 additionally comprising supplying a heat removal element and attaching the heat removal element to at least one of the electronic component, the substrate, or the plurality of layers.

19. The process of claim 18 wherein the heat removal element comprises a heat sink.

20. The process of claim 18 wherein the heat removal element comprises a block of material including a passage through which a fluid can be made to flow.

21. A process for fabricating a packaged electronic component, comprising:
providing a substrate having conductive vias;
forming routing elements which have first and second ends, where at least some of the first ends are connectable to a first electronic component and at least some of the second ends are connectable to vias on the substrate; and
electrically connecting the at least some of the second ends to the vias comprising a bonding operation;
electrically connecting the first electronic component to the at least some of the first ends.

22. A process for fabricating a plurality of packaged electronic components, comprising:
providing a substrate;
forming routing elements on the substrate which have first and second ends, where at least some of the first ends are electrically connectable to a first electronic component and at least some of the second ends are electrically connectable to a second electronic component;
attaching the first and second electronic components to the at least some of the first ends and second ends, respectively.

23. The process of claim 22 wherein along with the formation of routing elements having the first and second ends, other routing elements are formed having third and fourth ends and where the third ends are connected to the substrate while the fourth ends are electrically connected to at least one of the first or second electronic components.

24. The process of claim 22 wherein along with the formation of routing elements having the first and second ends, other routing elements are formed having third and fourth ends and where the third ends are connected to the substrate while the fourth ends are brought into proximity to one of the first or second electronic components but do not make electrically contact with either the first or second electronic components.

25. The process of claim 22 wherein substrate includes a passage for receiving a flow of fluid which may be used to remove heat from at least one of the electronic components.

26. The process of claim 22 wherein substrate includes a passage for receiving a flow of fluid which may be used to increase the uniformity of a temperature of the substrate when at least one of the electronic components is being used.

27. A process for fabricating a plurality of packaged electronic components, comprising:
providing a substrate;
forming routing elements which have first and second ends, where at least some of the first ends are electrically connectable to a first electronic component and at least some of the second ends are electrically connectable to a second electronic component;
establishing a thermally conductive connection between the substrate and routing elements; and
electrically connecting the first and second electronic components to the at least some of the first ends and second ends, respectively.

28. The process of claim 27 wherein the establishment of a thermally conductive connection comprises making a physical bond connecting the substrate and the routing elements.

29. The process of claim 28 wherein the physical bond connects the substrate and routing elements via at least one intermediate material.

30. A fabrication process for fabricating a package for holding an electronic component, comprising:
(a) forming and adhering a layer of material to a previously formed layer and/or to a substrate, wherein the layer comprises a desired pattern of at least one material; and
(b) repeating the forming and adhering operation of (a) a plurality of times to build up a configuration of conductive interconnect elements, wherein the plurality of layers are adhered to one another and comprise at least one of (i) at least one structural material and at least one sacrificial material or (ii) at least two structural materials one of which is a conductor and one of which is a dielectric; and
wherein at least one of the following is true:
(1) the package comprises metal electrodeposited or electroless deposited on a layer-by-layer basis where the height of at least some layers is set by a planarization operation that planarizes an interconnect material and at least one other material;
(2) the package comprises vias and traces that coexist on at least some layers;
(3) the package comprises at least one more coaxial interconnects;
(4) the package comprises interconnects having traces having at least two different widths;
(5) the package comprises interconnects comprising vias that have at least two different widths;
(6) the package comprises interconnects having trace thicknesses that are at least as thick as some planarized thicknesses of a dielectric material;
(7) the package comprises interconnects having trace thicknesses that are at least as thick as the differential height between some interconnect traces;
(8) the at least one layer of the package is formed using a process comprising: patterning a first material, applying a non-planar seed layer, electrodepositing a second material, and trimming off at least a portion of the deposited first material.
